(19) United States
(12) Patent Application Publication
(10) Pub. No.: US 2026/0203705 A1
(43) Pub. Date: Jul. 16, 2026

(54) PACKING MANAGEMENT TECHNIQUES WITH PACKING MOVEMENT SERIES, VARIABLE PACKAGING AND ACCOUNTABILITY

(71) Applicant: SAFEFLIGHTS INC., D.B.A. 14Bis Supply Tracking, Houston, TX (US)

(72) Inventors: Eleanor Mitch, Brookline, MA (US); Louis Chen, Marina, CA (US); Caroline Costa, Rio De Janeiro (BR); Rebecca Lee, New York, NY (US); Pradeep Mangalagiri, Naperville, IL (US)

(21) Appl. No.: 19/448,087

(22) Filed: Jan. 13, 2026

Related U.S. Application Data
(60) Provisional application No. 63/744,795, filed on Jan. 13, 2025.

(51) Int. Cl. G06Q 10/083; G06F 30/12; G06F 30/13

(52) U.S. Cl. CPC G06Q 10/0843; G06F 30/12; G06F 30/13

(57) ABSTRACT

Systems, devices and methods for managing packing for transportation are provided. According to some aspects of the invention, a packing management system including specialized computer hardware implements new graphical user interface (“GUI”) tools configured to aid a user in selecting a series of discrete, unitized orientations and/or movements for a package to be loaded and packed into a loading and packing area (a “packing movement series”). In some embodiments, the packing movement series is selected from a universal, standardized set of potential unitized orientations and movements for goods being packed and transported.

### CROSS-REFERENCE TO RELATED APPLICATION

This application claims the benefit of U.S. Provisional Patent Application No. 63/744,795, filed Jan. 13, 2025, the entire contents of which is hereby incorporated by reference in its entirety into the present application as if fully set forth herein.

### TECHNICAL FIELD

The present invention relates to the fields of packaging and package configuration for the shipping, transportation, travel and military industries. The present invention also relates to user interface tools and loading hardware for managing packaging.

### BACKGROUND

Packing science has its origins in ancient history, at the dawn of civilization. Early packing techniques included packages made from natural materials like wooden boxes and baskets made from reeds. Wrapping materials like papyrus and ceramic jugs (amphorae) followed. Packages were shipped by hand carrying, followed by pack animals, and then shipping by boats.

In modern times, goods are shipped by a wide variety of transportation modes and routes, including trucking, train and air freight, the latter being extremely fast (overnight from the U.S. to most locations on Earth). However, sea transport remains a mainstay of modern shipping. Although far slower than air freight and ground transportation, the low friction of water transport has a major cost advantage over all other modes of transportation. In modern sea shipping, large, standardized containers are hoisted onto larger and larger commercial shipping vessels, and may contain a wide assortment of different products. At a destination port, these containers can be easily offloaded onto alternate forms of transportation, like rail, to reach a final delivery location or warehouse destination closer to the final delivery location. At a standard 8 feet wide, by 8.5 feet high and up to 40 feet long, modern steel box shipping containers can be used to transport most goods in large numbers, and in a much more cost-effective manner than other bulk shipping approaches. Shipments in special, sensitive contexts have been increasing for many years, and are often more complex. For example, shipments from Earth to different atmospheric levels, and even to outer space, and deep-sea exploration may have specific shipping and packing requirements.

Although speed is of the utmost concern, some forms of transport, like air transport, benefit from greater space efficiency. But, generally speaking, efforts at greater space efficiency come at the cost of lower time efficiency, along with other unique costs. Some large-scale manufacturers, like IKEA, have developed flat-packing systems for shipping their products, allowing for minimal space between packages, great space efficiency, and little packing analysis. However, for example, damage to packages can increase with the greater space efficiency of flat-packing approaches, due to the lack of cushioning and space between packed objects.

There remains a need for more effective shipping and packing systems, devices and methods.

It should be noted that some of the disclosures set forth as background, such as, but not limited to, the above language under the heading “Background,” do not relate exclusively to prior art and the state of the art in the field(s) of the invention, and should not be construed as an admission with respect thereto.

### SUMMARY

Systems, devices and methods for managing packing for transportation are provided. According to some aspects of the invention, a packing management system including specialized computer hardware implements new graphical user interface (“GUI”) tools, included in a unique new human-machine interface (“HMI”) configured to aid a user in selecting and carrying out a series of discrete, unitized movements and/or orientations (and, in some embodiments, packing-related processes and procedural steps) for a package to be loaded and packed into a loading and packing area (a “packing movement series” or “set of packing movements and orientations”) as part of an optimized shipment loading plan for a set of goods, bins, packages or other objects and/or items to be transported. In some embodiments, the packing movement series includes unitized movements that are unique rotations for such a package, based on both the rotational characteristics of the package, and a unique packing pathway selected for the package. In some embodiments, the packing movement series is selected from a universal, standardized set of potential unitized movements and/or orientations for goods being packed and transported.

However, in some such embodiments, the control system also creates at least some of the orientations and/or movements of the packing movement series itself, without human interaction through an HMI (e.g., via application of a packing optimization and/or operations (a.k.a., a “PackOps”) algorithm, for example, using a neural network and/or other artificial intelligence (“AI”)). In some such embodiments, the control system generates and simulates a variety of potential unitized orientations and movements for use in such a set, and, in some such embodiments, the control system applies an algorithm to determine whether any or all such potential unitized orientations and movements will succeed. And, in some embodiments, the control system determines whether one or more of such a potential series of such potential unitized orientations and movements is optimal, and determines and indicates the degree of optimization for each such potential series, allowing a user to select from potential series of such potential unitized orientations and movements. In addition to selecting from and implementing such unitized orientations and movements, such an algorithm applies thresholds for weight, dimensions, center of weight (both within bins and within a loadable packing space in which bins are placed), load balance (both within bins and within a loadable packing space in which bins are placed), bin strength/fragility, movement, vibration isolation requirements, material requirements, packout time, and/or packout instruction time, in some embodiments. In some embodiments, such thresholds are applied as constraints by the control system, as are the available space(s) and shapes of a loadable packing space (e.g., one a shipping pallet and/or within a shipping container).

For example, in some such embodiments, the control system indicates a degree of packing efficiency optimization in a set of planned packing movements and orientations. As another example, in some embodiments, the control system indicates a degree of loading time efficiency optimization in such a set. In other embodiments, the control system indicates a degree of safety in grouping and placement of different objects (e.g., hazardous materials being placed away from humans or other objects likely to impact them). In some embodiments, the control system indicates a degree of timing efficiency of different movements and orientations, where time-conditions dictate an order or timing of some objects being packed (e.g., perishables or radioactive items). As yet another example, in some embodiments, the control system indicates a degree of sensitivity of some objects being packed, such as pressure sensitivity (e.g., in space and/or deep-sea contexts) and the need for interstitial spacing. And, in some embodiments, the control system selects the most optimal set based on maximizing any or all of the above degrees and indications, for example, according to a ranking of the priority for each of them, as may be selected by an administrative user.

In some embodiments, the control system also creates at least some of another “reverse series” of discrete, unitized orientations and movements for a package to be later unloaded and unpacked from the loading and packing area. In some embodiments, such a reverse series is generated simultaneously, in parallel, with such a packing movement series. And, in some embodiments, the control system generates multiple options for such a reverse series, and determines whether one or more of such a potential reverse series of such potential unitized orientations and movements is optimal, and indicates the degree of optimization for each such potential reverse series, allowing a user to select from potential reverse series of such potential unitized orientations and movements. In some embodiments, the degree of optimization for each such potential reverse series is included in the packing optimization algorithm. In some aspects of the inventions subject to this application, such an algorithm includes variables related to different dimensions, weights, shapes and rotational characteristics of packages. And, in some embodiments, such an algorithm includes variables related to “negative space” requirements, meaning spacing around objects that may be required, for example, for safety, or for expansion, contraction and variable pressure and forces in particular environments (e.g., loading areas in outer space and deep see environments).

In some embodiments, the control system includes 3D scanning hardware, capable of scanning and building a 3D model of a loadable packing space (including specifications of packing materials and devices within the packing space, such as shelving and netting (e.g., size of netting openings), and/or a set of goods, bins and/or packages (e.g., when placed adjacent to the loadable packing space, e.g., on or about a pre-loading area). Based on such a scan, in some such embodiments, the control system creates detailed exterior size, shape, weight, center of mass, fragility, material and/or balance specifications for each of the set of goods, bins and/or packages (e.g., as constraints for creating a packing movement series, and/or reverse series). However, in some embodiments, data including at least some of such specifications for each of the set of goods, bins and/or packages are, instead or in addition, uploaded from a database (e.g., in a.csv or other list, other digital or database format). In any event, the control system then performs operations based on such specifications, such as applying an algorithm generated by machine learning (e.g., reinforcement learning) any of the artificial intelligence techniques set forth in this application, in various embodiments.

In yet other embodiments, the goods, bins and/or packages subjected to such a potential series or reverse series are custom-sized and arranged packages of diverse goods, created based on needs communicated in real time. For example, in the context of military readiness and humanitarian relief efforts, readiness packages may be prepared for soldiers and other personnel, and may include such varied and time-sensitive goods as tools, spare parts and consumables. Some aspects of the inventions include working in multi-dimensional processes which include three dimensions or more such as 3-Dimensional (3D) and 4-Dimensional (“4D”) cutting stock and other approaches such as stable stack to create such custom packages. In some embodiments, such multi-dimensional cutting and packaging creates uniquely sized and shaped bins, with unique sectioning and customized compartments within a packing space. In some embodiments, the placement and rotation of such uniquely sized and shaped bins is then determined, executed and monitored with the aid of the control system. In this application, such embodiments may be referred to as multi-dimensional cutting stock with variable bin size and rotations” (or, “MDCSVR”) of which an example is “4D cutting stock with variable bin size and rotations” (or, “4DCSVR”). In various embodiments, a wide variety of irregularly shaped goods, bins and packages may be created and managed using such MDCSVR techniques. However, in some embodiments, at least some bins and/or packages may be or include standardized bins or bin materials provided by a user, the control system and/or a third party. For example, in some embodiments, such a standardized bin may be, or include, 463L pallets and/or ISU-90's. In some embodiments, such uniquely shaped bins may be created which are more regular or uniformly shaped than the goods to be held within them. In some such embodiments, internal voids may result from packing such irregularly shaped goods in such more regular or uniformly shaped bins. And, in some embodiments, the control system may create unique internal void-filling components to better fill such internal voids, and create unique cushioning elements, through similar cutting stock, or another material more suitable for filling internal voids in packaging (e.g., foam packaging cushions). In some embodiments, the control system creates multiple cutting patterns for creating such uniquely shaped bins and void-filling components, and evaluates and compares the efficiencies of each such pattern, selecting a pattern with the greatest efficiency.

In additional aspects, the control system includes both local computer system(s) for (“on-device processing”) and one or more remote server(s), networked with the local computer system(s), made a client and server by software on both the local computer system(s) (client) and the server computer system(s). In some embodiments, the local computer system(s) may continue to develop and apply a packing optimization algorithm locally, even during a network outage, while it may also be used by remote servers of the control system more widely, when the network connections are re-established, via unique edge computing aspects of the invention(s). In some embodiments, a local, edge computing part of the control system is provided, which runs an offline version and instance of an optimization program on the local computer system(s), which uses less computational resources than a more resource-intensive version maintained on the remote servers of the control system (the “online version”). For example, in some embodiments, the offline version and instance of the optimization program does not implement more complex and resource-intensive programming techniques (such as linear programming techniques, in some embodiments), whereas the online version does. However, it should also be noted that, in some embodiments, linear programming techniques are not implemented in a remote version or a local version. In some embodiments, the control system isolates the local, edge computing part of the control system (e.g., discontinuing network connections with the local, edge computing part) when information (e.g., such as the specifications of packages) being managed by the control system at that time is of a sensitive nature (e.g., governmentally classified information). And, in some such embodiments, an indicator is included within the HMI and/or GUI, indicating to a human user whether the version of the part of the control system they are working with is online or offline from remote servers of the control system.

In some embodiments, the control system provides estimates regarding the costs, e.g., in terms of time, monetary, personnel and other resources associated with implementing an optimized shipment loading plan prior to implementing it, as well as estimates of alternative optimized shipment loading plans, with or without one or more goods, bins and/or packages included. In one aspect of the inventions, a user may alter the set of goods, bins and/or packages subjected to such a potential series or reverse series based on those estimates (e.g., if the cost or risk per pound or shipping dollar is far greater or lower with or without one or more of the set of goods, bins and/or packages).

In some embodiments, data may be recorded by the control system and/or control unit, in data repositories of a memory thereof, and used both to build and apply a packing optimization and/or operations (a.k.a., a “PackOps”) algorithm, for example, using a neural network and/or other artificial intelligence (“AI”) technologies

In some embodiments, a PackOps algorithm, or other AI-generated algorithm, is created by the control system with reinforcement learning techniques, based on data related to the actual space efficiency and fitment indicators experienced after implementing a packing movement series and/or reverse series. However, in various embodiments, a wide variety of AI training techniques may be implemented, as an alternative, or in addition to reinforcement learning techniques.

Further aspects of the invention will be set forth in greater detail, below, with reference to the particular figures.

### BRIEF DESCRIPTION OF THE DRAWINGS

The features and advantages of the example embodiments of the invention presented herein will become more apparent from the detailed description set forth below when taken in conjunction with the following drawings.

FIG. 1 is a perspective view of some example elements of a system for managing packing for transportation, comprising a control system (such as the example control system set forth below, in reference to FIG. 3) operating within an example product loading and packing environment, in accordance with some embodiments.

FIG. 2 is a view of an example GUI, which may be used by a user of a control system (such as the example control system set forth below, in reference to FIG. 3) to aid in managing the packing of goods, in accordance with some example embodiments of the invention.

FIG. 3 is a schematic block diagram of some elements of a control system in accordance with some example embodiments of the invention.

FIG. 4 is another schematic block diagram of some elements of a control system in accordance with some example embodiments of the invention.

FIG. 5 is another perspective view of some additional aspects of the system for managing packing for transportation of FIG. 1, illustrating a series of orientations and movements being executed, in accordance with user selections via a GUI (such as the example GUI depicted in FIG. 2, in accordance with some embodiments.

FIG. 6 is a process flow diagram, illustrating several example steps that may be carried out by a control system, such as the example control system set forth in reference to FIG. 3, carrying out methods for managing the packing of packages, in accordance with some additional embodiments.

FIG. 7 is another process flow diagram, illustrating several example steps that may be carried out by a control system, such as the example control system set forth in reference to FIG. 3, carrying out additional methods for managing the packing of packages, in accordance with some additional embodiments.

FIG. 8 is a perspective drawing of an example elements of a packaging optimization subsystem which may include and/or included within a control system, such as the example control system set forth above, in reference to FIG. 3, implementing methods related to the creation of optimized shipping packages from cutting stock, in accordance with some embodiments.

FIG. 9 is a perspective view drawing of an example customized and uniquely sized and shaped bin, created by a packaging optimization subsystem of a control system, such as the example packaging optimization subsystem discussed above, in reference to FIG. 8.

FIG. 10 is a perspective view drawing of additional example elements of an alternative embodiment of a system for managing packing for transportation, comprising a control system (such as the example control system set forth above, in reference to FIG. 3) operating within another example product loading and packing environment, in accordance with some embodiments.

FIG. 11 is another process flow diagram, illustrating several example steps that may be carried out by a control system, such as the example control system set forth in reference to FIG. 3, carrying out additional methods for managing the packing of packages with the aid of autonomous robotic hardware, in accordance with some additional embodiments.

### DETAILED DESCRIPTION

The example embodiments of the invention presented herein are directed to systems, devices, methods and computer program products for managing packing of products for transportation, which are now described herein. This description is not intended to limit the application of the example embodiments presented herein. In fact, after reading the following description, it will be apparent to one skilled in the relevant art(s) how to implement the following example embodiments in alternative embodiments.

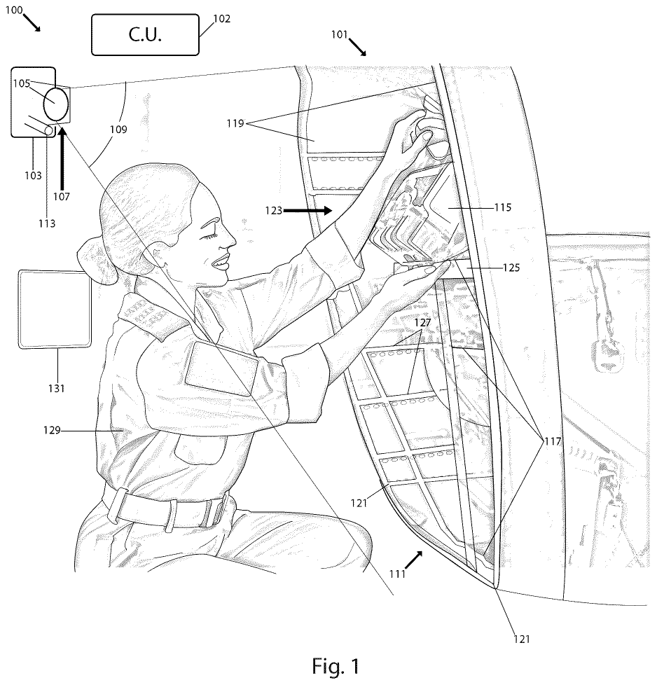

Embodiments of packing management systems including, but not limited to, a control system including computer hardware and software, carrying out example methods of packing products for transportation in accordance with some aspects set forth in this Specification are depicted in FIGS. 1 through 9. The following is a list of defined components and/or aspects and reference numbers therefor, as used throughout the figures:

| Reference No. | Component |
|---|---|
| 100 | system for managing packing for transportation |
| 101 | product loading and packing environment |
| 102 | on-premises control unit |
| 103 | camera or other optical sensor |
| 105 | wide-angle lens |
| 107 | vantage point |
| 109 | wide field of view |
| 111 | loading area |
| 113 | rangefinder or other distance measurer |
| 115 | part or other goods or package |
| 117 | floors (of loading area 111) |
| 119 | walls (of loading area 111) |
| 121 | corners (of loading area 111) |
| 123 | loadable space |
| 125 | internal shelving |
| 127 | mounting struts |
| 129 | loading engineer user |
| 131 | interactive touchscreen display |
| 200 | display |
| 201 | graphical user interface (“GUI”) |
| 203 | orientation, positioning and movement GUI tools |
| 205 | rows of selectable sub-tools |
| 207 | selectable sub-tools |
| 209 | GUI tool |
| 211 | first row of selectable sub-tools |
| 213 | wall-relative position indicating GUI tool |
| 215 | side indicators |
| 217 | far side indicator |
| 219 | left-most side indicator |
| 221 | right-most side indicator |
| 223 | orientation-indicating GUI tool |
| 225 | orientation indicators |
| 227 | narrow and broad side laying orientation sub-tool |
| 229 | wide side indicators |
| 231 | overall layout-indicating GUI tool |
| 233 | 3D model |
| 300 | control system |
| 301 | input/output device |
| 303 | memory device |
| 305 | long-term data storage device |
| 307 | processor(s) |
| 309 | server(s) and/or on blockchain(s) |
| 311 | local machine(s) |
| 313 | cameras and microphones |
| 314 | sensor(s) |
| 315 | internet of things or other ubiquitous computing devices |
| 317 | ERP |
| 319 | mouse, keyboard, touchscreen and/or other display |
| 320 | smartphone |
| 400 | control system |
| 401 | overall control system |
| 403 | main operating system |
| 405 | package scanning hardware and software module |
| 407 | loading bay layout scanning module |
| 409 | packing optimization neural network |
| 411 | set of virtual machines |
| 413 | specialized software |
| 415 | remote resources |
| 417, 419 & 421 | communications channels |
| 503 | rotational movement arrow |
| 504 | upward movement arrow |
| 505 | floor |
| 507 | oblique angle indicator |
| 600 et | example method steps |
| seq. | |
| 700 et | example method steps |
| seq. | |
| 800 | packaging optimization subsystem |
| 801 | cutting stock panel |
| 803 | local control system |
| 805 | cutting and scoring actuator(s) |
| 807 | laser cutter |
| 809 | linear cuts (in cutting stock panel 801) |
| 811 | scoring lines |
| 901 | customized and uniquely sized and shaped bin |
| 903 | internal partitions |
| 905 | customized, unique internal compartments |
| 1000 | system for managing packing for transportation |
| 1001 | on-premises robotic loader |
| 1002 | on premises control unit |
| 1003 | complex loading area |
| 1005 | curved, faceted and/or angled walls |
| 1007 | curved, faceted and/or angled shelves |
| 1009 | curved, faceted and/or angled compartments |
| 1011 | curved, irregular bracing |
| 1013 | curved and/or irregular luggage bays |
| 1015 | ready-to-load packages |
| 1017 | on-board shelf |
| 1019 | robot-navigable floor |
| 1021 | loadable space |
| 1023 | field of view |
| 1100 et | example method steps |
| seq. | |

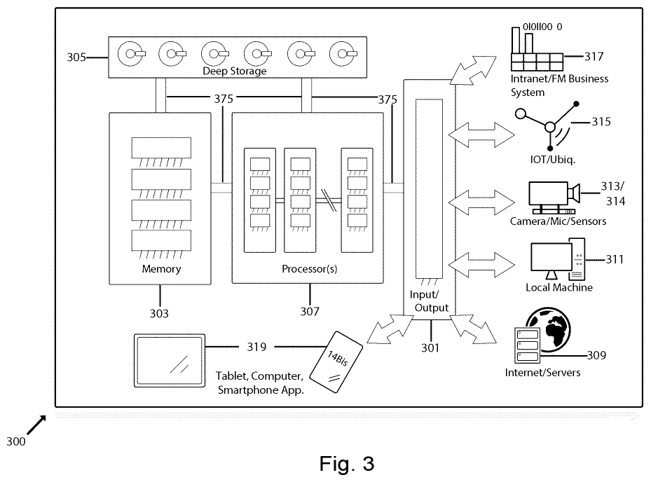

FIG. 1 is a perspective view of some example elements of a system 100 for managing packing for transportation, comprising a control system (such as the example control system set forth below, in reference to FIG. 3) operating within an example product loading and packing environment 101, in accordance with some embodiments. In some embodiments, such a control system includes, or is included within, a local on-premises control unit, such as example on premises control unit 102. In some such embodiments, such an on-premises control unit 102, and such a control system, comprise a camera or other optical sensor 103, which, in some such embodiments, may include a wide-angle lens 105, an may be mounted from a vantage point 107 creating a wide field of view 109, including an entire loading area, such as the example loading area shown as loading area 111. And, in some embodiments, on premises control unit 101 includes a rangefinder or other distance measurer 113, such as a LIDAR or SONAR based distance measurer. As will be explained in more detail below, in some such embodiments, the control system may calculate distances and angles relative to lens 105 of object(s) included within loading area 111. For example, some such objects may include good(s) or a package(s), such as example complex aircraft part or other goods or package 115. But, in some embodiments, such objects may include interior or other features of a loading area, such as one or more floors, such as example floors 117, one or more walls, such as example walls 119, and/or one or more corners, such as example corners 121, which define a loadable space 123 of the loading area 111.

And, in some embodiments, by determining the distance of such an object, and the apparent movement of such an object, and its outer surface, across the field of view 109, the control system and control unit 102 may build a three-dimensional (3D) model of the object, and map the outer surface of the object. As will be apparent to those of skill in the art, a large variety of alternative 3D modeling and scanning technologies may also be applied, in addition to or as an alternative to, a camera, LIDAR, SONAR, rangefinder and other object scanning technology, to determine the location and build a detailed 3D model of such objects. And, in some embodiments, the control system and/or control unit 102 also scan and build a model of the loading area 111 itself, along with its internal features, such as example internal shelving 125 and example mounting struts 127, and enables a user to engage in a virtual, 3D tour of the loading area, before, during and after a series of packing movements takes place, such as a simulated walkaround of the loading area and packages loaded, or in the process of being loaded, within it. In some embodiments, the control system and control unit 102 determine and record detailed dimensional data and/or other specifications data for each such good, package or other object to be loaded in to loading area 111, based on such scanning. Although, in some embodiments, such detailed dimensional data and/or other specifications data may be provided from another data source, such as a dimensions and specifications database (e.g., provided by a manufacturer of the good, package or other object).

In any event any and all of such data may be recorded by the control system and/or control unit, in data repositories of a memory thereof, and used both to build and apply a packing optimization and/or operations (a.k.a., a “PackOps”) algorithm, for example, using a neural network and/or other artificial intelligence (“AI”) technologies. And, in some embodiments, a user, such as example loading engineer user 129, may refer to an HMI display and/or other input/output device, such as example interactive touchscreen display 131, to aid in executing a set of movements and/or orientations to load such goods and/or packages into loading area 111. For example, in some embodiments, such a user may interact with GUI tools of such a display and/or other input/output device to execute and/or modify of a packing movement series, or reverse series, of such movements and/or orientations, as discussed elsewhere in this application, in accordance with some embodiments. As discussed elsewhere in this application, the control system and control unit 102 may comprise, or be comprised in, a packing management system including specialized computer hardware implements such GUI tools configured to aid a user in selecting a series of discrete, unitized orientations and/or movements for a package to be loaded and packed into a loading and packing area (a “packing movement series”). In some embodiments, the packing movement series is selected from a set of universal, standardized and unitized potential orientations and movements for goods being packed and transported.

However, in some such embodiments, the control system and/or control unit also creates at least some of the orientations and/or movements of the packing movement series. In some such embodiments, the control system and/or control unit generates and simulates a variety of potential unitized orientations and movements for use in such a set, and, in some such embodiments, the control system applies the PackOps algorithm to determine whether any or all such potential unitized orientations and movements will succeed.

And, also with respect to creating and implementing a PackOps algorithm using AI, in some embodiments, the control system and/or control unit determines whether one or more of such a potential series of such potential unitized orientations and movements will optimize packing efficiency (e.g., space, time or economic efficiency, in various embodiments) in comparison to other loading options. In some such embodiments, the control system and/or control unit determines and indicates both 1. whether one or more of such a potential series of such potential unitized orientations and movements is optimal, and 2. the degree of optimization for each of such potential series—and allows a user to select from potential series of such potential unitized orientations and movements.

For example, in some such embodiments, the control system indicates a degree of packing efficiency optimization. As another example, in some embodiments, the control system indicates a degree of loading time efficiency optimization.

In some embodiments, the control system also creates at least some of another “reverse series” of discrete, unitized orientations and movements for a package to be later unloaded and unpacked from the loading and packing area. In some embodiments, such a reverse series is generated simultaneously, in parallel, with such a packing movement series. And, in some embodiments, the control system generates multiple options for such a reverse series, and determines whether one or more of such a potential reverse series of such potential unitized orientations and movements is optimal, and indicates the degree of optimization for each such potential reverse series, allowing a user to select from potential reverse series of such potential unitized orientations and movements. In some embodiments, the degree of optimization for each such potential reverse series is included in the packing optimization algorithm.

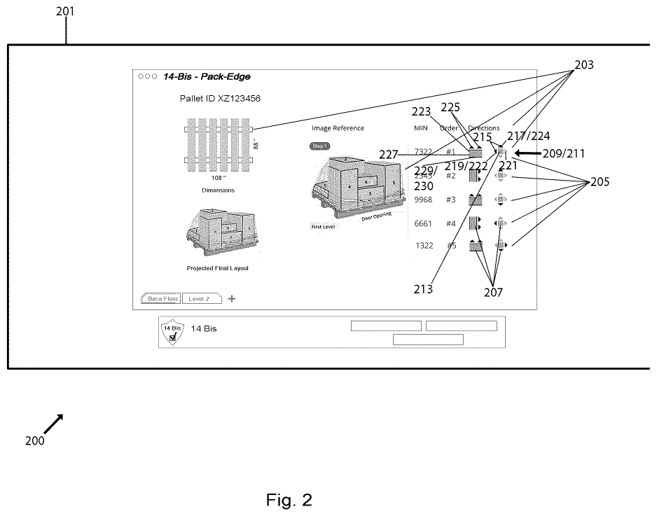

FIG. 2 is a view of an example display 200 including a GUI 201, which may be used by a user of a control system (such as the example control system set forth below, in reference to FIG. 3) to aid in managing the packing of goods, in accordance with some example embodiments of the invention. As discussed elsewhere in this application, such a GUI may include one or more GUI tools and sub-tools, to so aid a user (such as example loading engineer user 129, discussed above) in executing a packing movement series. And, as discussed elsewhere in this application, such a packing movement series may include a variety of standardized and unitized potential orientations, positions and movements for goods and/or packages being packed and transported. For example, a series of orientations, positions and movements for goods and/or packages are indicated in orientation, positioning and movement GUI tools 203 are provided, in the form of rows 205 of selectable sub-tools, such as the example selectable sub-tools 207. One such GUI tool 209, appears as an example first row 211, corresponding with a first orientation, position and/or movement of goods and/or packages to be loaded into a loading area. And one such sub-tool is example wall-relative position indicating GUI tool 213. In some embodiments, wall-relative position indicating GUI tool 213 includes one or more side indicators 215, which indicate whether and which walls of a loading area, and/or floor thereof, a particular, identified good and/or package must be placed against. For example, in some embodiments, at least one separate side indicator is provided to indicate each wall of a loading area (e.g., each of 4 lateral walls of a square or rectangular loading area. As pictured, the farthest wall (e.g., from an opening of a loading area) is indicated by a far side indicator 217, which is furthest upward of the side indicators for wall-relative position indicating GUI tool 213, on the display 200. Similarly, a left-hand side of the loading area (when a user is facing the opening of the loading area) is indicated by a left-most side indicator 219 of the side indicators, and a right-hand side of the loading area (when a user is facing the opening of the loading area) is indicated by a right-most side indicator 221 of the side indicators for wall-relative position indicating GUI tool 213. And, because the far side indicator 217 and the left-most side indicator 219 are presented with a unique boldness, shading, color or other enhancement 222 and 224, respectively, a user is instructed by example first row 211 and wall-relative position indicating GUI tool 213 to move the first good or package against those indicated sides of the loading area.

In some embodiments, an orientation-indicating GUI tool 223 is provided, including one or more orientation indicators 225, which indicate the rotational position of the first good or package must have when placed into the loading area, for optimized packing. For example, in some embodiments, orientation-indicating GUI tool 223 includes a narrow and broad side laying orientation sub-tool 227, indicating whether the first good or package is to have its narrowest or broadest side placed against a bottom of the loading area (or a bottom of a floor of a loading area, in some embodiments). In some embodiments, narrow and broad side laying orientation sub-tool 227 includes one or more wide side indicators 229 (shown with a unique boldness, shading, color or other enhancement 230) which, when shown in a downward position on display 200, indicates that the widest side of the first good or package should be oriented downward on the bottom of the loading area.

Thus, in conjunction with one another, wall-relative position indicating GUI tool 213, and orientation-indicating GUI tool 223 indicate that the first good or package should be oriented with its broadest side against the floor of the loading area, and that the first good or package should be moved tightly against the far wall and the left wall (and into the far-left corner) of the loading area. And, after executing such an indicated orientation and movement, the control system may scan the loaded good and/or package, determine whether it matches the orientation and movement indicated, and report (e.g., via another alert GUI aspect of the GUI) whether corrective action is required, to the user. In some embodiments, as discussed in further detail below, the user may reject a suggested positioning and/or orientation of the good and/or package, for example, by repeatedly moving the good and/or package into a different position or orientation than that indicated. In some such embodiments, the control system may then accept the chosen position and orientation of the user, as a constraint, and apply an optimization algorithm to a remainder of a packing job, as will be discussed in further detail below.

In any event, the user may next proceed to an additional, next-lower row in the GUI 201, (of rows 205) including additional selectable sub-tools, and follow the additional orientations and movements indicated therein, and so on, until the full set of packing movements of the packing series is completed.

In some embodiments, additional GUI tools and sub-tools may also be provided. For example, in some embodiments, an overall layout-indicating GUI tool 231 is provided, which includes a 3D model 233 of the loading area, and final position and orientation of a set of goods and/or packages to be loaded into the loading area, based on GUI 201.

It should be noted that, although the particular examples of wall-relative position indicating GUI tools, an orientation-indicating GUI tools, and a layout-indicating GUI tools are provided in the present figure, a wide variety of alternative forms and types of movements, positioning and orientation-indicating GUI tools may also, or alternatively, be used, in alternative embodiments. The specific examples provided do not limit the scope of the inventions, as will be readily apparent to those of skill in the art.

FIG. 3 is a schematic block diagram of some elements of a control system (hereinafter, the “system” or “control system”) 300, in accordance with some example embodiments of the present invention. In some example embodiments, the control system incorporates a non-transitory machine-readable medium storing instructions that, when executed by one or more processors, execute various aspects of the present invention described herein. The generic and other components and aspects described herein are not exhaustive of the many different systems and variations, including a number of possible hardware aspects that might be used, in accordance with the example embodiments of the invention. Rather, the control system 300 is an example embodiment.

Control system 300 includes an input/output device 301, a memory device 303, long-term data storage device 305, and processor(s) 307. The processor(s) 307 is (are) capable of receiving, interpreting, processing and manipulating signals and executing instructions for further processing and for output, pre-output and/or storage in and outside of the system. The processor(s) 307 may be general or multipurpose, single- or multi-threaded, and may have a single core or several processor cores, including microprocessors. Among other things, the processor(s) 307 is/are capable of processing signals and instructions for the input/output device 301, to cause a user interface to be provided or modified for use by a user on hardware, such as, but not limited to, computer system peripheral devices, such as a mouse, keyboard, touchscreen and/or other display 319, with specialized tools (e.g., for aiding in optimizing and packing goods and packages within a loading area, as set forth in this application) and/or presentation and input-facilitating software (as in a graphical user interface, a.k.a. a “GUI”) (e.g., on local machine(s) 311, display 319 or smartphone 320) or other human-machine interface (“HMI”) that might or might not be embedded in other systems/devices or robot(s)-human(s)-machine(s) interfaces that may or may not be embedded in other systems/devices.

For example, user interface aspects, such as graphical “windows,” “buttons” and data entry fields, may present via, for example, a display, any number of selectable options and/or data entry fields. When the option and/or data entry field is selected, such selection causes aspects of the control system to command other aspects of the control system to track, access and modify data related to managing and optimizing the packing of goods and/or products, in accordance with aspects of the invention. In some embodiments, some of such aspects are managed by an ERP, or superuser, which may be included within, or in communication with, the control system, to create, scan and store information, tags and/or films and patterns, in relation to those data, and to provide digital signatures, identification codes or information, and record them in a secure manner on a network (e.g., the Internet and/or another network incorporating a blockchain). For example, and as explained in greater detail elsewhere in this application, the control system may provide standard EDI components, and negotiated new EDI components, generated by algorithms and/or artificial intelligence subsystems of the control system, and, in response to data interchanged, facilitate the creation of a smart contract and/or token on a blockchain, related to any of those data. In some embodiments, the control system may record and label parameters for the management of a product and/or service by the control system and other data systems, and provide secure identifiers and/or other data related to the asset to the control system, where it is stored (e.g., on long-term data storage device 305, or server(s) and/or on blockchain(s) 309). The processor(s) 307 may execute instructions stored in memory device 303 and/or long-term data storage device 305, and may communicate via system bus(ses) 375. Input/output device 301 is capable of input/output operations for the system, and may include and communicate through input and/or output hardware, and instances thereof, such as a computer mouse, scanning device or other sensors, actuator(s), communications antenna (ae), keyboard(s), smartphone(s) and/or PDA(s), networked or connected additional computer(s), camera(s) or microphone(s), a mixing board(s), real-to-real tape recorder(s), external hard disk recorder(s), additional movie and/or sound editing system(s) or gear, speaker(s), external filter(s), amp(s), preamp(s), equalizer(s), computer display screen(s) or touch screen(s). Such input/output hardware could implement a program or user interface created, in part, by software, permitting the system and user to carry out the user settings and input discussed in this application. Input/output device 301, memory device 303, data storage device 305, and processor(s) 307 are connected and able to send and receive communications, transmissions and instructions via system bus(ses) 375. Data storage device 305 is capable of providing mass storage for the system, and may be or incorporate a computer-readable medium, may be a connected mass storage device (e.g., flash drive or other drive connected to a Universal Serial Bus (USB) port or Wi-Fi), may use back-end (with or without middle-ware) or cloud storage over a network (e.g., the Internet) as either a memory backup for an internal mass storage device or as a primary memory storage means, or may simply be an internal mass storage device, such as a computer hard drive or optical drive. Generally speaking, the system may be implemented as a client/server arrangement, where features of the system are performed on a remote server, networked to the client and made a client and server by software on both the client computer and server computer. Also generally speaking, the system may be implemented as middleware, whereby it provides output and other services to an external system. In any event, the system may include, or include network connections (e.g., wired, WAN, LAN, cellular (e.g., 5G), ethernet, satellite, and/or Internet connections) with, any of the example devices or auxiliary devices and/or systems, shown as Internet server(s) and blockchain(s) 309, local machine(s) 311, cameras and microphones 313, sensor(s) 314, internet of things or other ubiquitous computing devices 315, ERP 317, scanner 319 and smartphone 320. Similarly, the control system 300 is capable of accepting input from any of those auxiliary devices and systems, and modifying stored data within them and within itself, based on any input or output sent through input/output device 301.

Input and output devices may deliver their input and receive output by any known means, including, but not limited to, any of the hardware and/or software examples shown as internet server(s) and blockchain(s) 309, local machine(s) 311, which may run locally stored software within them (e.g., inventory management system(s) or MICROSOFT EXCEL) cameras and microphones 313, sensor(s) 314, internet of things or other ubiquitous computing devices 315, ERP 317, display 319 and smartphone 320.

While the illustrated example of a control system 300 in accordance with the present invention may be helpful to understand the implementation of aspects of the invention, any suitable form of computer system known in the art may be used—for example, in some embodiments, a simpler computer system containing just a processor for executing instructions from a memory or transmission source. The aspects or features set forth may be implemented with, and in any combination of, digital electronic circuitry, hardware, software, firmware, middleware or any other computing technology known in the art, any of which may be aided with external data from external hardware and software, optionally, by networked connection, such as by LAN, WAN, satellite communications networks, 5G or other cellular networks, and/or any of the many connections forming the Internet. The system can be embodied in a tangibly-stored computer program, as by a machine-readable medium and propagated signal, for execution by a programmable processor. The many possible method steps of the example embodiments presented herein may be performed by such a programmable processor, executing a program of instructions, operating on input and output, and generating output and stored data. A computer program includes instructions for a computer to carry out a particular activity to bring about a particular result, and may be written in any programming language, including compiled and uncompiled and interpreted languages and machine language, and can be deployed in any form, including a complete program, module, component, subroutine, or other suitable routine for a computer program.

In some embodiments, the control system includes specialized hardware and software to allow operation in a wide variety of network environments. For example, in some embodiments, the control system carries out any or all of the steps and other techniques set forth in this application despite intermittent network connections. For example, in some such embodiments, if the control system experiences a temporary or other loss of connection to a network server, local intranet server, other network and/or blockchain(s), any data recordation and communications steps may be paused and/or queued until such time as the connection(s) are restored, at which time those steps may be executed. In some such embodiments, despite such a loss of such a connection, subsequent steps after any step including data recording through such a network, on a blockchain, set forth in any method set forth in this application, may still be carried out, and the control system may utilize data recorded in an alternative format, in a nearby, local data storage device, such as long-term data storage device 305 or a data storage device included in ERP 317, instead of data recorded through such a network, on a blockchain. For example, in some such embodiments, such data recorded in an alternative format, in a nearby, local data storage device includes a record signifying that a blockchain record will be made, along with a record of the data to be recorded on the blockchain. In some such embodiments, in which data recordation through such a network, on a blockchain is a prerequisite to such a subsequent step, such data recorded in an alternative format, in a nearby, local data storage device substitutes as the prerequisite for actual recordation on the blockchain, for such subsequent steps.

As another example, in some embodiments, the control system continues to carry out any or all of the steps and other techniques set forth in this application in an efficient manner, during inconsistent network performance and/or altered type(s) of network connections (e.g., any of the control system's satellite network, local area network, cellular network, and/or wired network connections, etc., failing, slowing and being reestablished over time). For example, in some such embodiments, if the control system experiences a temporary or other loss of availability, or reduced performance, of a network server, local intranet server, other network and/or blockchain(s), but other networks remain or become available, any data recordation and communications steps may be queued, re-attempted and/or rerouted through such available, alternative networks, until such time as the connection(s) are restored, at which time those steps may be executed. In some such embodiments, despite such a loss of availability or reduced performance of such a server or network, subsequent steps after any step including data recording through such a network, on a blockchain, set forth in any method set forth in this application, may still be carried out, and the control system may utilize data recorded in an alternative format, in a nearby, local data storage device, such as long-term data storage device 305 or a data storage device included in ERP 317, instead of data recorded through such a network, on a blockchain. For example, in some such embodiments, such data recorded in an alternative format, in a nearby, local data storage device includes a record signifying that a blockchain record will be made, along with a record of the data to be recorded on the blockchain. In some such embodiments, in which data recordation through such a network, on a blockchain is a prerequisite to such a subsequent step, such data recorded in an alternative format, in a nearby, local data storage device substitutes as the prerequisite for actual recordation on the blockchain, for such subsequent steps.

In some embodiments, the control system may divide network communications and execute them in different parts over different networks. In some such embodiments, such a division of network communications may be made to improve the encryption of such communications, e.g., by segmenting independently illegible aspects of the communication, across each network.

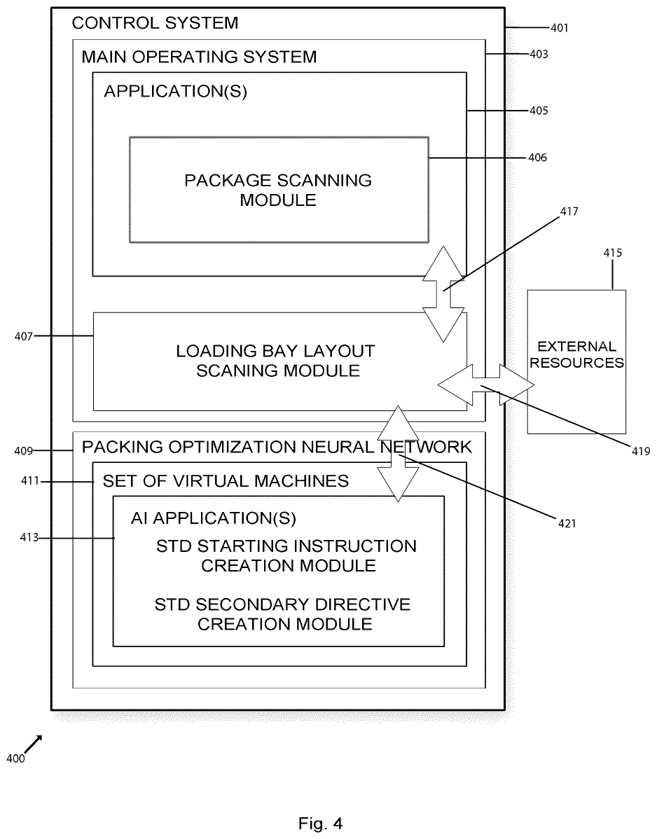

FIG. 4 is another schematic block diagram of some elements of a control system 400 in accordance with some example embodiments of the invention. In some embodiments, such a control system may include any of the components for control systems set forth above, in FIG. 3, within overall control system 401. However, in addition, in some embodiments, control system 400 may include more specific additional hardware and software modules, such as a main operating system 403, including a package scanning hardware and software module 405 and a loading bay layout scanning module 407. As mentioned above, in some embodiments, package scanning hardware and software of such a module may include a camera or other optical sensor and a rangefinder, for example, and such software may aid in performing a 3D scan to build a 3D model, in some embodiments. As also discussed elsewhere in this application, control system 400 may also include artificial intelligence (“AI”) modules, in some embodiments, such as example packing optimization neural network 409. In some embodiments, such a neural network may be run on a computer system that is separate and intermittently connected with and/or remote from main operating system 403, in some embodiments. For example, in some embodiments, packing optimization neural network 409 may include and/or be run on, remote servers, such as set of virtual machines 411. And, in some embodiments, packing optimization neural network 409 may include specialized software 413, such as a starting and/or next instruction creation software module, which may generate the first and second of an optimized order, orientation and positioning of packing movements, respectively. Of course, although potentially run on separate hardware, any of the above components may communicate with each other and remote resources 415, in some embodiments, through communications channels 417, 419, and 421, respectively.

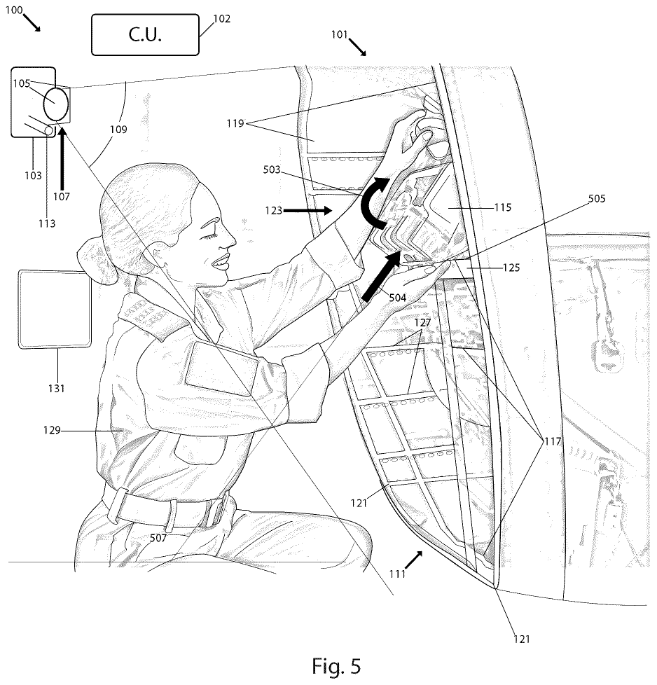

FIG. 5 is another perspective view of some additional aspects of the system for managing packing for transportation of FIG. 1, illustrating a series of orientations and movements being executed, in accordance with user selections via a GUI (such as the example GUI depicted in FIG. 2, in accordance with some embodiments). In some embodiments, a user may be provided with GUI tools having more complex movements and groups of movements indicated, to optimally fit a good or package in a confined space with complex boundaries. Thus, as shown in the present figure, the user is both rotating and inserting example complex aircraft part or other goods or package 115, in rotational movement shown by example rotational movement arrow 503, and moving it in an upwards direction, as shown upward movement arrow 504, which may be defined by an oblique angle with respect to floor 505 of internal shelving 125, onto which it will be placed, which oblique angle is demonstrated by acute angle indicator 507, any of which movement arrows and indicators may be indicated within a GUI incorporating an image or 3D rendering of FIG. 5 elements.

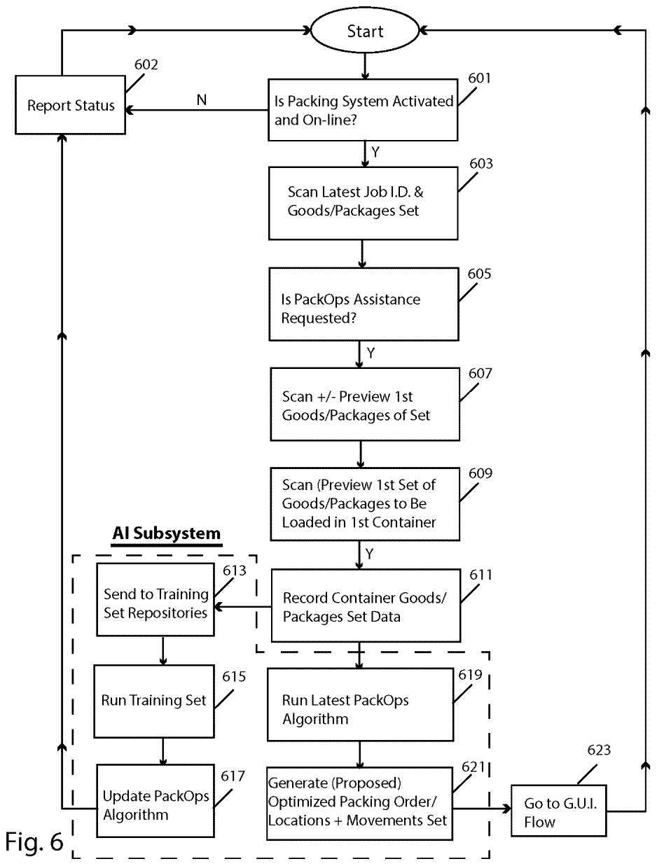

FIG. 6 is a process flow diagram, illustrating several example steps 600 that may be carried out by a control system, such as the example control system set forth in reference to FIG. 3, carrying out methods for managing the packing of packages, in accordance with some additional embodiments.

Beginning with step 601, in some embodiments, the control system first determines whether subsystems of the control system related to packing (packing system module(s)) are properly operating (e.g., “activated”) and ready (e.g., connected for communications with the remainder of the control system, via, for example, the Internet). If so, in some embodiments, the control system proceeds to step 603, in which it accesses data related to a packing job, which packing job includes the identification of a set of goods and/or packages to be loaded into a loading area (such as example loading area 111, discussed above) of a transportation container. However, it should be noted that, in step 603, in some embodiments, a packing job may not yet include a pre-identified set of goods and/or packages to be loaded into a loading area. Instead, in some such embodiments, the control system may create a set of goods and/or packages to be loaded into a loading area by scanning one or more goods and/or packages to be so loaded, e.g., one-by-one, creating an identifier, and recording the identifier and other data related to each such good and/or package as a set of goods and/or packages to be loaded into a loading area.

If the packing system is not activated and ready, the control system may instead proceed to step 602, in which it may alert a user (e.g., via a G.U.I. aspect) that such packing system module(s) are not activated and ready, in some embodiments, and may return to the starting position.

Assuming that the control system determined that packing system module(s) are activated and ready, and proceeded to step 603, the control system may next proceed to step 605, in which it determines whether a user has requested packing operations (“PackOps”) assistance from the control system. For example, in some embodiments, a user may indicate that he, she or it is requesting PackOps assistance by activating a GUI tool, such as a clickable button, indicating and communicating to the control system that PackOps assistance is requested.

If such PackOps assistance is being requested, the control system may next proceed to step 607, in which it begins PackOps assistance of the user by presenting a display aspect (e.g., a GUI tool including a user-navigable 3D model of the loading area), and/or, in some embodiments performing a 3D scan of the loading area, and building the 3D model of the loading area. And, in some embodiments, the control system also presents a display aspect (e.g., another GUI tool including another user-navigable 3D model) of a first set of goods and/or packages and/or performs a 3D scan of the good and/or packages to building a 3D model of each of the goods and/or packages within the first set of goods and/or packages.

At this point, the control system may proceed to step 611, in which it records the data related to a packing job, including the identification of a set of goods and/or packages to be loaded into a loading area, and other data related to each such good and/or package of the set of goods and/or packages to be loaded into a loading area, and may proceed to step 613, in which it may send these data to repositories of training data within, and generally activate and communicate with, an artificial intelligence (“AI”) subsystem of the control system. In some embodiments, such an AI subsystem may include a neural network and such repositories of training data, generating a PackOps algorithm, in some embodiments, as will be discussed in more detail below. As in other AI neural networks, the AI subsystem may trained on such training data sets, in step 615, based on one or more desired outcomes with respect to packing optimization, such as loading goods and/or packages with greater space and/or time efficiency and/or less breakage, based on additional data related to the outcome of movements and orientations for packing goods and/or packages, discussed in this application. And, based on the outcomes of such training, the AI subsystem may update the PackOps algorithm to be applied by the control system, in step 617, generating better-optimized packing movements and/or orientations for goods and/or packages in the future.

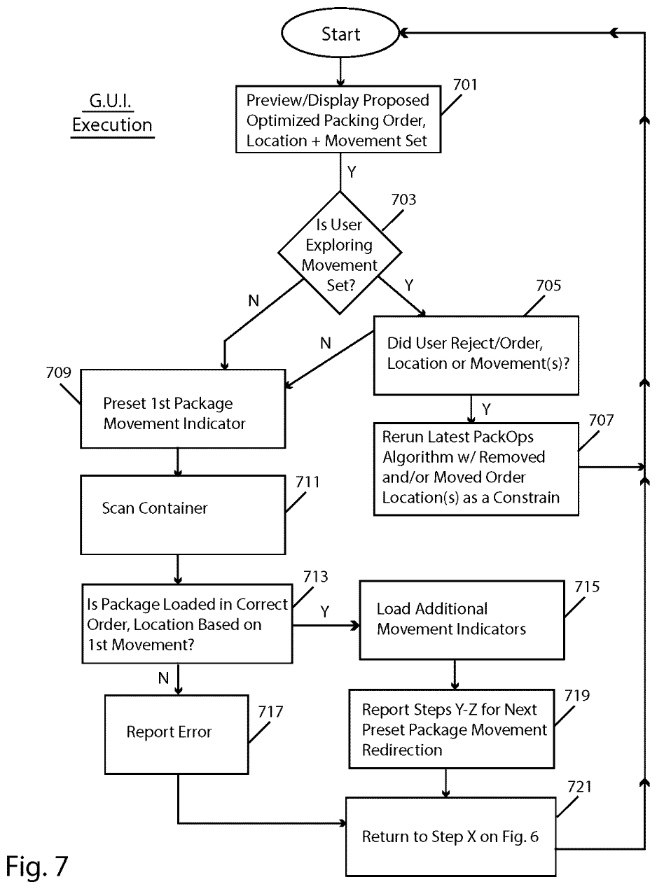

And, in step 619, the control system may apply the latest PackOps algorithm, to the data related to a packing job, to predict and generate an optimized set of packing movements and orientations, and the order thereof. Based on the results of such an application of the latest PackOps algorithm, the control system may proceed to present a series of GUI aspects, upon presenting the generated optimized set of packing movements and orientations, and the order thereof, which will be discussed in greater detail below, with reference to FIG. 7. The control system may then return to the starting position.

FIG. 7 is another process flow diagram, illustrating several example steps 700 that may be carried out by a control system, such as the example control system set forth in reference to FIG. 3, carrying out additional methods for managing the packing of packages, in accordance with some additional embodiments. As discussed above, in some embodiments, the control system proceeds to present a series of GUI aspects to a user, to aid in executing an optimized packing order, including a set of optimized packing locations and/or packing movements, and an order thereof, to pack goods and/or packages within a loading area. Beginning with step 701, the control system may first present a proposed set of optimized packing locations and/or packing movements, and order thereof, to pack goods and/or packages within a loading area—e.g., within a GUI representation of such a set of movements, orientations and/or orders, such as that discussed with reference to FIG. 2, above. In some embodiments, a user may review the proposed set, and explore the set, via a specialized GUI, such as a 3D demonstration of such a set being carried out on a 3D rendering of the goods and/or packages being loaded via the set, into the loading area, in step 703. In some embodiments, the user may also simply begin executing the set of movements, orientations and/or orders, which execution the control system may monitor (e.g., via LIDAR or photographic sensors and movement and object scanning, recognition and analysis). However, in some embodiments, the user may affirmatively indicate that he, she or it is not in agreement with one or more of the proposed set of movements, orientations and/or orders, in step 705. For example, a user may so affirmatively indicate that they are not in agreement by clicking on a GUI indicator stating that a movements, orientations and/or orders is rejected, and will not be executed. In some embodiments, a user may so affirmatively indicate that they are not in agreement by (e.g., repeatedly) moving goods and/or packages in a different direction(s) or orientation(s) than indicated in the presented set. In any event, if the user has so indicated rejection, the control system may proceed to step 707, in which it adopts a new movement proposed by the user (e.g., the repeated movement) as a constraint, and then re-running the PackOps algorithm, in step 707. The control system may then return to the starting position.

If, however, the user did not so indicate rejection, and instead simply begins executing the set of movements, orientations and/or orders, the control system may proceed to step 709, in which it presents and/or demonstrates a first movement, orientation, of the set, to be executed by the user. The control system may then scan the good and/or package so loaded, in step 711, and determines, in step 713, whether the package has been properly so loaded. If so, the control system proceeds to step 715, in which it proceeds to similarly present and/or demonstrate GUI aspects for a second movement, orientation, of the set, to be executed by the user, and so on, with similar error reporting, in step 719. In step 721, the control system may then return to step 623 of FIG. 6, above, and then return to the starting position.

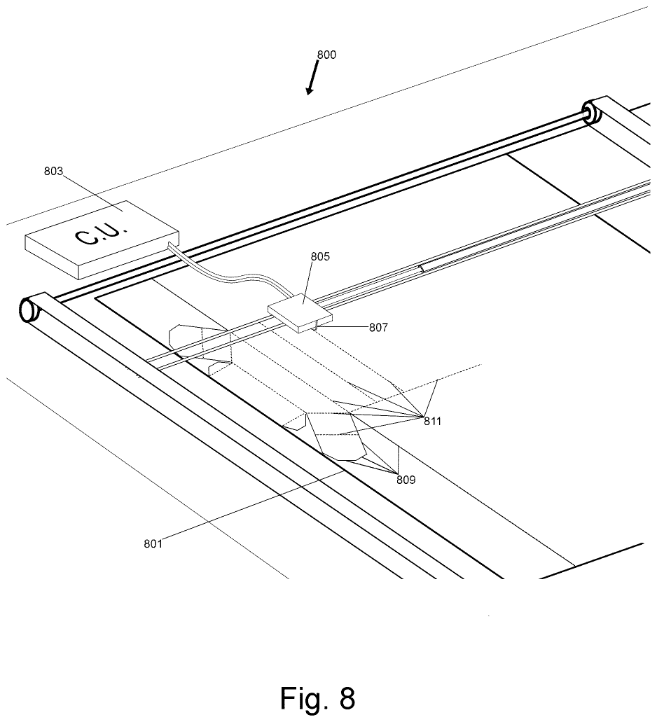

FIG. 8 is a perspective drawing of an example elements of a packaging optimization subsystem 800 which may include and/or included within a control system, such as the example control system set forth above, in reference to FIG. 3, implementing methods related to the creation of optimized shipping packages from cutting stock, such as the example panel of cutting stock shown as cutting stock panel 801, in accordance with some embodiments. As discussed elsewhere in this application, in some embodiments, systems and techniques for the creation of optimized packages from cutting stock may be based on multi-dimensional (e.g., 3D or more dimensions such as 4D or more) considerations. For example, in some such embodiments, the control system implements packaging optimization algorithms, to create uniquely sized and shaped bins, with unique sectioning and customized compartments within a packing space to accommodate a set of goods to be shipped, as well as pre-determined placements and rotations for packing the bins into a loadable space for shipping. Such techniques are referred to in this application as “Multi-Dimensional cutting stock with variable bin size and rotations” (or, “MDCSVR”). In some embodiments, the placement and rotation of such uniquely sized and shaped bins is also executed and monitored with the aid of the control system, in accordance with techniques set forth elsewhere in this application.

The example cutting stock panel 801 as shown may be formed from any suitable sheet material for constructing bins, such as shipping boxes, including, but, not limited to any of the following sheet materials: corrugated cardboard, plastic, any kraft paper (such as coated kraft paper), wood, paper, Acrylonitrile butadiene styrene (ABS), polycarbonate, Polyethylene terephthalate glycol (PetG), a fabric, a foam or a sheet metal (such as aluminum).

In some embodiments, the packaging optimization subsystem 800 includes a local control system 803 connected for communications with, and powering a cutting and scoring actuator(s) 805, which may be any suitable form of cutting actuator(s) known in the art for cutting and/or scoring sheet materials. For example, in some embodiments, cutting and scoring actuator(s) 805 may include a laser cutter 807, configured to be positioned and moved (e.g., mounted on a positionable armature with a belt drive and a linear actuator, mounted at ninety (90) degree angles from one another) at any point above and onto a cutting board and sheet material placed thereon. As another example, in some embodiments, cutting and scoring actuator(s) 805 may include a blade, similarly configured to be positioned and moved (e.g., mounted on a similar positionable armature) at any point above and onto a cutting board and sheet material placed thereon. In any event, in some embodiments, such a cutting and scoring actuator(s) 805 may be controlled by the control system and/or packaging optimization subsystem 800 to create cuts, such as the example linear cuts 809, and scoring lines, such as the example scoring lines shown as scoring lines 811 which may then be folded, e.g., by a separate, folding actuator (not pictured, but also included within, or communicatively connected with, the local control system 803, in some embodiments) to create custom sized and/or shaped bins and, in some such embodiments, customized internal partitions within such custom sized and/or shaped bins, as discussed further below.

It should be noted that, although the example of MDCSVR has been provided above, in some embodiments, other methods may be used to create varied bin sizes and rotations. For example, in some embodiments, a packaging optimization subsystem in accordance with aspects of the present application creates optimized bin sizes through multi-dimensional molding, as may be used in additive manufacturing techniques. As another example, in some embodiments, a packaging optimization subsystem in accordance with aspects of the present application creates optimized bin sizes through other additive manufacturing techniques (such as layer-by-layer deposition methods).

In various embodiments, a wide variety of irregularly shaped goods, bins and packages may be created and managed using such MDCSVR techniques. However, in some embodiments, at least some bins and/or packages may be or include standardized bins or bin materials provided by a user, the control system and/or a third party. For example, in some embodiments, such a standardized bin may be, or include, 463L pallets and/or ISU-90's. In some embodiments, such uniquely shaped bins may be created which are more regular or uniformly shaped than the goods to be held within them. In some such embodiments, internal voids may result from packing such irregularly shaped goods in such more regular or uniformly shaped bins. And, in some embodiments, the control system may create unique internal void-filling components to better fill such internal voids, and create unique cushioning elements, through similar cutting stock, or another material more suitable for filling internal voids in packaging (e.g., foam packaging cushions). In some embodiments, the control system creates multiple cutting patterns for creating such uniquely shaped bins and void-filling components, and evaluates and compares the efficiencies of each such pattern, selecting a pattern with the greatest efficiency.

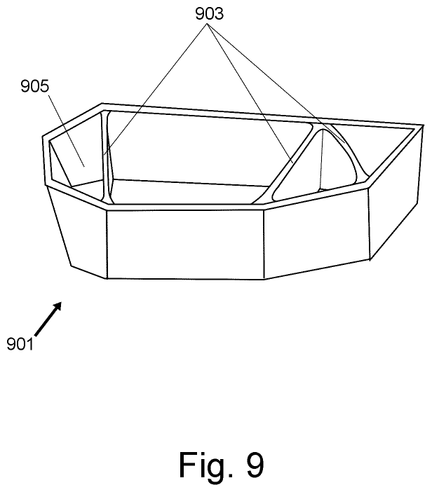

FIG. 9 is a perspective view of an example customized and uniquely sized and shaped bin 901, created by a packaging optimization subsystem of a control system, such as the example packaging optimization subsystem 800, discussed above. As also discussed above, in some embodiments, such a customized and uniquely sized and shaped bin 901 may be created by such a control system and/or packaging optimization subsystem 800, based on thresholds and constraints dictated by a packing optimization algorithm, such as the packing optimization algorithms discussed above.

In some embodiments, such a customized and uniquely sized and shaped bin 901 includes customized internal partitions example internal partitions 903. In some embodiments, such customized internal partitions include customized angles, lengths, depths, curves and other dimensions, creating customized, unique internal compartments 905 between them, within customized and uniquely sized and shaped bin 901. As discussed above, such customized internal partitions 903, dimensions, and customized, unique internal compartments 905 may be created by a packaging optimization subsystem, such as the example packaging optimization subsystem 800, discussed above, by cutting, scoring and folding actuators. And, in some embodiments, such customized internal partitions 903, dimensions, and customized, unique internal compartments 905 may be created by a control system and/or packaging optimization subsystem based on thresholds and constraints dictated by a packing optimization algorithm, as discussed elsewhere in this application.

The customized and uniquely sized and shaped bin 901 may then be subjected to both: 1. optimized internal packing of goods within it, and 2. pre-determined placements and rotations for packing the bins into a loadable space for shipping, in accordance with techniques set forth in the present application, such as MDCSVR techniques.

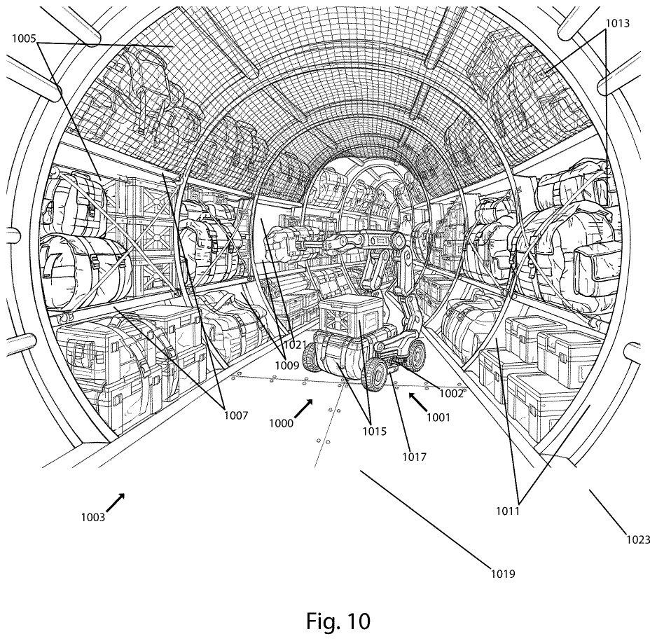

FIG. 10 is a perspective view drawing of additional example elements of an alternative embodiment of a system 1000 for managing packing for transportation, comprising a control system (such as the example control system set forth above, in reference to FIG. 3) operating within another example product loading and packing environment, in accordance with some embodiments. In some embodiments, such a control system includes, or is included within, a local, on-premises robotic loader 1001 control unit, such as example on premises control unit 1002.

In some such embodiments, robotic loader 1001 may operate within a complex loading area, such as the example loading area shown as complex loading area 1003, such a complex loading area having curved, faceted and/or angled walls 1005 and curved, faceted and/or angled shelves 1007 and/or curved, faceted and/or angled compartments 1009. Additionally, in some embodiments, loading area 1003 may also include or abut curved, irregular bracing 1011, such as bracing serving to support the curved, faceted and/or angled walls 1005, as may be required in certain unique transportation vehicles and environments, such as submersible vehicles and spacecraft used in deep sea environments and space travel, in some embodiments. As a result, a variety of curved and/or irregular luggage bays 1013 may be available for loading and/or unloading by a user within complex loading area 1003, in some embodiments.

In some such embodiments, such a robotic loader 1001 and/or such an on-premises control unit 1002, and such a control system, comprise one or more on-board sensor(s) and actuator(s). For example, in some embodiments, the robotic loader 1001 and/or control unit 1002 include one or more camera(s), for viewing and interacting with the packages, such as the example ready-to-load packages 1015, shown resting on an on-board shelf 1017 of robotic loader 1001, and for viewing and interacting with aspects of the loading area 1003. And, in some embodiments, on premises control unit 101 includes a rangefinder or other distance measurer, such as a LIDAR or SONAR based distance measurer, for aiding in defining the location and/or position of packages and aspects of loading area 1003. As discussed above, in some such embodiments, the control system may calculate distances, angles and other features of packages, objects, shelves, interior features of bays, walls (such as example walls 1005), floor space (such as example floor space of example flat, yet curved, wheeled robot-navigable floor 1019), and loadable space 1021 and other aspects of the loading area 1003 (such as curved and/or irregular luggage bays 1013), with the aid of such sensor(s) and/or rangefinder(s).

And, in some embodiments, by determining the distance of such an object, and the apparent movement of such an object, and its outer surface, across a field of view 1023 of a sensor of robotic loader 1001, the control system and control unit 1002 may build a three-dimensional (3D) model of the object, and map the outer surface of the object. As will be apparent to those of skill in the art, a large variety of alternative 3D modeling and scanning technologies may also be applied, in addition to or as an alternative to, a camera, LIDAR, SONAR, rangefinder and other object scanning technology, to determine the location and build a detailed 3D model of such objects. And, in some embodiments, the control system and/or control unit 1002 also scan and build a model of the loading area 1003 itself, along with its internal features.

In some embodiments, the control system and control unit 1002 determine and record detailed dimensional data and/or other specifications data for each such good, package or other object to be loaded in to loading area 1003, based on such scanning. Although, in some embodiments, such detailed dimensional data and/or other specifications data may be provided from another data source, such as a dimensions and specifications database (e.g., provided by a manufacturer of the good, package or other object).

In any event any and all of such data may be recorded by the control system and/or control unit, in data repositories of a memory thereof, and may be used both to build and apply a packing optimization and/or operations (a.k.a., a “PackOps”) algorithm, for example, using a neural network and/or other artificial intelligence (“AI”) technologies, in some embodiments.

And, in some embodiments, a human user, such as example loading engineer user (not pictured), may refer to an HMI display and/or other input/output device, such as example interactive touchscreen display 131, discussed above, to aid in executing a set of movements and/or orientations to load such goods and/or packages into loading area 1003. For example, as discussed above, in some embodiments, such a user may interact with GUI tools of such a display and/or other input/output device to execute and/or modify of a packing movement series, or reverse series, of such movements and/or orientations, in accordance with some embodiments. And, as also discussed elsewhere in this application, the control system and control unit 1002 may comprise, or be comprised in, a packing management system including specialized computer hardware implements such GUI tools configured to aid a user in selecting a series of discrete, unitized orientations and/or movements for a package to be loaded and packed into a loading and packing area (a “packing movement series”). In some embodiments, the packing movement series is selected from a set of universal, standardized and unitized potential orientations and movements for goods being packed and transported.

However, and also as mentioned above, in some such embodiments, the control system and/or control unit 1002 also creates at least some of the orientations and/or movements of the packing movement series. More specifically, in some such embodiments, the control system and/or control unit generates and simulates a variety of potential unitized orientations and movements for use in such a set, and, in some such embodiments, the control system applies the PackOps algorithm to determine whether any or all such potential unitized orientations and movements will succeed.

And, also with respect to creating and implementing a PackOps algorithm using AI, in some embodiments, the control system and/or control unit determines whether one or more of such a potential series of such potential unitized orientations and movements will optimize packing efficiency (e.g., space, time or economic efficiency, in various embodiments) in comparison to other loading options. In some such embodiments, the control system and/or control unit determines and indicates both 1. whether one or more of such a potential series of such potential unitized orientations and movements is optimal, and 2. the degree of optimization for each of such potential series- and allows a user to select from potential series of such potential unitized orientations and movements.

For example, in some such embodiments, the control system indicates a degree of packing efficiency optimization. As another example, in some embodiments, the control system indicates a degree of loading time efficiency optimization.

In some embodiments, the control system also creates at least some of another “reverse series” of discrete, unitized orientations and movements for a package to be later unloaded and unpacked from the loading and packing area. In some embodiments, such a reverse series is generated simultaneously, in parallel, with such a packing movement series. And, in some embodiments, the control system generates multiple options for such a reverse series, and determines whether one or more of such a potential reverse series of such potential unitized orientations and movements is optimal, and indicates the degree of optimization for each such potential reverse series, allowing a user to select from potential reverse series of such potential unitized orientations and movements. In some embodiments, the degree of optimization for each such potential reverse series is included in the packing optimization algorithm.

And, in some embodiments, rather than relying on a human user to manually perform each of the series, and/or reverse series, of discrete, unitized orientations and movements, in some embodiments, the control system issues commands to one or more local, on-premises robotic loader(s), such as example robotic loader 1001, discussed above. For example, in some embodiments, discrete, unitized commands are issued to the robotic loader 1001 from a control system remote from robotic loader 1001, for creating each and every discrete, unitized movement and/or orientation required to be performed in the series (and/or reverse series) by the robotic loader 1001. In some embodiments, each of the series, and/or reverse series, of discrete, unitized orientations and movements is translated into a series of such corresponding commands by the remote control system, after scanning for networked robotics connected with, or available to, the remote control system, and determining appropriate corresponding commands based on the number and type(s) of robotic loaders discovered, as will be discussed in greater detail below. And, in some embodiments, the remote control system issues a firmware update to one or more of the type(s) of robotic loaders discovered, if needed to accept and/or effectuate the corresponding commands and/or if a checksum or other firmware integrity check indicates the need for a firmware update for any of the robotic loaders discovered. The commands may then be issued to each of the robotic loaders discovered, in a controlled sequence (e.g., using TCP/IP protocols) to ensure that the series is carried out in the correct order.

And, in some embodiments, after executing any of the discrete, unitized movements, the robotic loader 1001 may issue feedback to the remote control system, related to successful or unsuccessful loading of a package, good or other object into an expected final position expected to result from each such discrete, unitized movement. For example, in some embodiments, the robotic loader 1001 sends sensor data indicating whether an expected final position of the package, good or other object matches one or more expected visual, location, orientation and other aspects of a fully loaded package expected to result from each such discrete, unitized movement. And, in some embodiments, such sensor data may be proprioception data, indicating whether the package, good or other object is in an expected mid-loading position matching an expected mid-loading aspect of the package, good or other object at a planned time of proprioception. In some embodiments, such feedback is issued using a higher speed communications protocol, such as UDP.

In some embodiments, a plurality of robotic loaders may be used. In some such embodiments, a plurality of arrest commands may be issued, to one or more such a plurality of robotic loaders, at different times, to prevent the one or more of such a plurality of robotic loaders does not interfere with movements of another of the plurality of robotic loaders, or other moving objects. In some embodiments, such arrest commands may be issued by other robotic loaders, e.g., issuing the orders via low power direct communication, such as Bluetooth or Zigbee. In some embodiments, any of the robotic loaders may also self-arrest, and issue alert(s), e.g., through the remote control system, in the even that a discrete, unitized movement commanded is perceived not to have occurred as expected, or if an expected to result from the discrete, unitized movement is perceived (e.g., through proprioception or visual confirmation) not to have occurred.

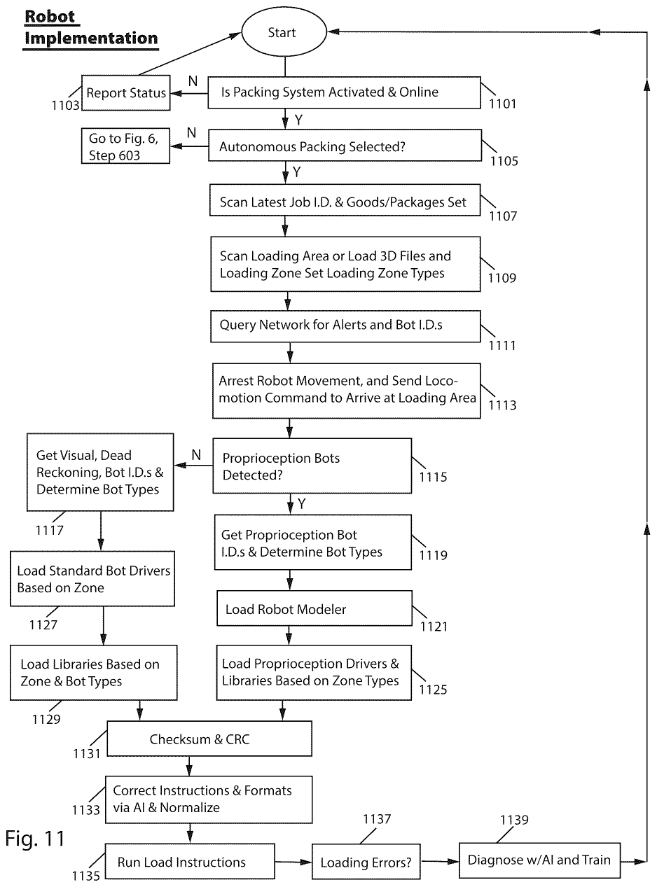

FIG. 11 is a process flow diagram, illustrating several example steps 1100 that may be carried out by a control system, such as the example control system set forth in reference to FIG. 3, above, carrying out additional methods for managing the packing of packages with the aid of autonomous robotic hardware, in accordance with some additional embodiments.

Beginning with step 1101, in some embodiments, the control system first determines whether subsystems of the control system related to packing (e.g., packing system module(s)) are properly operating (e.g., “activated”) and ready (e.g., connected for communications with the remainder of the control system, via, for example, a secure network and/or fieldbuses). If the packing system is not activated and ready, the control system may instead proceed to step 1103, in which it may alert a user (e.g., via a G.U.I. aspect) that such a packing subsystem is not activated and ready, and in some embodiments, may return to the starting position.

If the packing subsystem is ready, at step 1101, in some embodiments, the control system proceeds to step 1105, in which it determines whether a user (e.g., an administrative user) has selected a control system setting selecting an “autonomous packing” mode of operation for the control system. If not, in some embodiments, the control system proceeds to step 603 of FIG. 6, discussed above, to carry out certain non-autonomous packing aspects. In any event, in some embodiments an autonomous packing mode involves the control system serving as a remote control system, issuing commands to one or more robotic devices, causing all or some of a set of discrete, unitized movements and/or orientations required to be performed in a planned series (and/or reverse series) of such movements and/or orientations. As discussed above, in some embodiments, all or some of such a set of discrete, unitized movements and/or orientations will then be conducted by automated robotic loaders, such as any of the robotic loaders discussed above, and/or robotic peripheral devices. In some embodiments, such an autonomous packing mode is entered and managed via specialized computer hardware and software, which may include specialized software causing the control system, and its peripheral devices, to perform the following additional steps.

The control system next proceeds to step 1107, in which it accesses data related to a packing job, which packing job includes the identification of a set of goods and/or packages to be loaded into a loading area (such as example complex loading area 1003, discussed above). However, it should be noted that, in step 1107, in some embodiments, a packing job may not yet include a pre-identified set of goods and/or packages to be loaded into a loading area. Instead, in some such embodiments, the control system may create a set of goods and/or packages to be loaded into a loading area by scanning one or more goods and/or packages to be so loaded, e.g., one-by-one, creating an identifier, and recording the identifier and other data related to each such good and/or package as a set of goods and/or packages to be loaded into a loading area. And, in subsequent step 1109, the control system may proceed to either scan the loading area itself, and any shelves, walls, supports, bays, or other aspects of the loading area, to create a 3D model of the loading area, or simply load a pre-existing 3D model of the loading area, and the control system may set a loading zone type, which may cause it to set a control mode (e.g., a slower, more cautious control mode for more sensitive loading areas (e.g., spacecraft loading areas being detected). In some embodiments, the control system may compartmentalize data related to the packing job, including the identification of a set of goods and/or packages to be loaded into a loading area, and other data related to each such good and/or package of the set of goods and/or packages to be loaded into a loading area, and send these data to separate, secure data repositories of training data, and generally activate and communicate with, an artificial intelligence (“AI”) subsystem of the control system. In some embodiments, such an AI subsystem may include a neural network and such repositories of training data, generating a PackOps algorithm, in some embodiments, as discussed elsewhere in this application. As in other AI neural networks, the AI subsystem may trained on such training data sets based on one or more desired outcomes with respect to packing optimization, such as loading goods and/or packages with greater space and/or time efficiency and/or less breakage, based on additional data related to the outcome of movements and orientations for packing goods and/or packages, discussed in this application. And, based on the outcomes of such training, the AI subsystem may update the PackOps algorithm to be applied by the control system, generating better-optimized packing movements and/or orientations for goods and/or packages in the future. And the control system may apply the latest PackOps algorithm, to the data related to a packing job, to predict and generate an optimized set of packing movements and orientations, and the order thereof. Based on the results of such an application of the latest PackOps algorithm, the control system may proceed to create an optimized set of packing movements and orientations, and the order thereof, as discussed in greater detail elsewhere in this application.

In any event, in step 1111, and because an autonomous packing mode of operation has been set, in step 1105, the control system may proceed to query a local network of peripheral devices, in some embodiments, and determine if robotic loader devices (such as any of the robotic loaders set forth above) are available for use by the control system (i.e., are ready to receive commands from the control system) and record a unique identifier and/or network address for each such rob. In some embodiments, the control system may next issue specialized commands to each such identified robotic loader device, causing it to arrest movement and, in some embodiments, to navigate to the loading area, in step 1113. In some embodiments, the control system determines, based on such unique identifiers and whether they indicate a make, model or other indicator of capabilities of the respective robotic loader device(s), whether any of the robotic loader devices include proprioceptive capabilities, in step 1115. In some embodiments, proprioceptive capabilities, or, proprioception, in the context of robotic loaders means that the robotic loader includes hardware capable of determining the robotic loader's position, and/or the position of an articulating moving piece of the robotic loader (e.g., a robotic arm), and/or forces applied to it (including gravity), for example, by sensors, sensor/motors, sensor/actuators, gauges or other hardware. If none of the robotic loader devices include proprioceptive capabilities, at step 1115, the control system proceeds to step 1117, in which it instead determines other, potentially more conventional types of robotic loader devices are instead present within the network, and takes further steps based on that information (which steps are discussed further below). If the control system determines that at least some of the robotic loader devices includes proprioceptive capabilities, at step 1115, however, the control system proceeds to step 1119 in which it may interpret and/or record the unique identifiers of the proprioception-capable robotic loader devices, and determines a specific type of the robotic loader (e.g., a make and model of the robotic loader), and its packing-movement relevant specifications. In some embodiments, the control system then proceeds to step 1121, in which it may select and activate a specialized hardware and/or software-based modeler, to create a simulation of each of the identified robotic loaders. In some embodiments, the control system may even run a full simulation of all of the packing movements and orientations planned in the optimized set, based on the 3D model of the loading area and the packages, goods or other objects in the area, and change the planned commands to the robotic loader, and test via simulation again if errors are projected to occur in the simulation, to ensure that commands will be interpreted and carried out correctly. In some embodiment, an LLM may be used, and trained on multiple commands and real world results (labelled correct or an error) to aid in determining the likelihood of errors, in the simulation. And, in some embodiments, the LLM may suggest adjustments to commands or firmware, to address and/or overcome the errors in the real-world loading area, after running the simulation.

In any event, in step 1125, the control system may next select, summon and load the most suitable, optimal firmware, among available options, to aid the robotic loaders in carrying out the planned packing movements and orientations in the optimized set. For example, in some embodiments, the control system so selects, summons and loads drivers and libraries based on the identified make and model of the robotic loader, and the type of zone the loading area is in. If the loading zone is of a type labelled as sensitive, such as a spacecraft environment, greater care and slower speed may be implemented, both in the planning of packing movements and orientations planned in the optimized set, and in their execution. Similarly, in steps 1127 and 1129, if non-proprioceptive-capable robotic loaders are to be used, the control system may load firmware, drivers and libraries most appropriate for those types of robotic loaders (and zones). Following that, in order to ensure that firmware updates have been performed correctly, a checksum and/or CRC routine may be carried out in subsequent step 1131.

Any potential errors or deficiencies discussed above, either in firmware or the projected results of a loading plan carried out in a simulation, may next be addressed in corrected commands, and the format of commands may be modified to address different interpretations by different forms of robotic loaders being detected, in step 1133. For example, in some embodiments, if a robotic loader communicates in Zigbee only, rather than TCP, an AI sub-system of the control system, using a neural network trained on translating commands for each protocol, may be used to transform the command data for the packing movements and orientations planned in the optimized set.

The control system may next proceed to step 1135 in which it issues a set of commands corresponding with the planned packing movements and orientations planned in the optimized set, based on the simulations discussed above. And, as with the results of the simulation(s), discussed above, any detected real world errors, instep 1137, as the robotic loaders carry out the optimized set may be recorded and logged, and used as training data for the AI sub-component(s) of the AI sub-system, in step 1139.

The control system may then return to the starting position.

We claim:

1. A system for managing packing of packages, comprising:
a control system comprising computer hardware and software comprising:
a movement and orientation optimization sub-module;
a loading area dimensional assessment sub-module, comprising scanning hardware, capable of scanning 3D space within loading areas;
a proposed package set scanning sub-module;
wherein said control system is configured to:
implement said movement and orientation optimization sub-module to select a limited set of standardized packing movements and orientations based on said scanned 3D space.

2. The system for managing packing of packages of claim 1, wherein said movement and orientation optimization sub-module generates a packing movement series.

3. The system for managing packing of packages of claim 2, wherein the packing movement series includes said selected limited set of standardized packing movements and orientations based on said scanned 3D space.

4. The system for managing packing of packages of claim 3, wherein the system provides said set of standardized packing movements and orientations based on said scanned 3D space on a specialized GUI including a serial movement-indicating sub-tool.

5. The system for managing packing of packages of claim 3, wherein the system provides said set of standardized packing movements and orientations based on said scanned 3D space on a specialized GUI including a serial orientation-indicating sub-tool.

6. The system for managing packing of packages of claim 4, wherein the serial movement-indicating sub-tool includes a wall location sub-tool comprising an instruction for placing a longest side of a package against a wall location.

7. The system for managing packing of packages of claim 4, wherein the serial orientation-indicating sub-tool includes a corner location sub-tool comprising an instruction for placing a corner of a package against a corner location.
